(19) United States
(12) Patent Application Publication
(10) Pub. No.: US 2014/0255640 A1
(43) Pub. Date: Sep. 11, 2014

(54) SAPPHIRE SUBSTRATE STRUCTURE FOR PATTERN ETCHING AND METHOD OF FORMING PATTERN SAPPHIRE SUBSTRATE

(71) Applicant: PHECDA TECHNOLOGY CO. LTD., TAIPEI CITY (TW)

(72) Inventor: YONG-FA HUANG, Zhunan Township, Miaoli County (TW)

(21) Appl. No.: 13/909,694

(22) Filed: Jun. 4, 2013

(30) Foreign Application Priority Data
Mar. 5, 2013 (TW) 102107725

(51) Int. Cl. H01L 31/0236; H01L 31/18

(52) U.S. Cl. CPC H01L 31/02366; H01L 31/18
USPC 428/64.1; 428/472.2; 427/402; 216/24; 430/325

(57) ABSTRACT

The present invention discloses a sapphire substrate structure for pattern etching and method of forming a pattern sapphire substrate (PSS). The sapphire substrate after pattern etching is suitable to be used as the substrate of a light-emitting device. The sapphire substrate structure comprises a photoresist layer, an underlayer, and a sapphire substrate. The photoresist layer is a uniform layer made of G-line photoresist, I-line photoresist, 248 nm DIN photoresist, or 193 nm Arf photoresist and comprises a flat surface. The underlayer is a uniform layer made of an organic or inorganic compound and comprises a flat surface. The sapphire substrate is formed by epitaxy, while the photoresist layer and the underlayer are formed by coating. After the sapphire substrate structure is formed, it is step by step transformed into a pattern sapphire substrate through an exposure/development process, an etching process, and a cleaning process subsequently.

### CROSS-REFERENCE TO RELATED APPLICATION

This application claims priority from Taiwan Patent Application No. 102107725, filed on Mar. 5, 2013 in Taiwan Intellectual Property Office, the contents of which are hereby incorporated by reference in their entirety.

### BACKGROUND OF THE INVENTION

1. Field of the Invention

The present invention is related to a sapphire substrate structure for pattern etching and method of forming a pattern sapphire substrate, and particularly, to a sapphire substrate structure for providing an excellent substrate for a light-emitting device.

2. Description of the Related Art

By using the Photo-electronic Effect, modern light-emitting devices are able to convert electric energy into light forms via the recombination of stimulated electrons and holes. Semiconductor processes are already applied to mass-produce this kind of device. The modern light-emitting device with the most universal applications is the light-emitting diode (LED). Light-emitting diodes possess the advantages of long device lifetime, luminescence light-emitting, low power consumption, fast reaction speed, and zero warm-up time, etc. By adopting the semiconductor processes, light-emitting diodes further comprise the features of small size, robustness against impact, and easy to mass-produce, etc. Moreover, light-emitting diodes can be fabricated as an array or a small optical device, based on the application demands.

In recent years prices of energy sources are increasing rapidly. Therefore, pursuing energy saving and GHG mitigation have become a global tendency. To further extend the application field of the light-emitting diodes, both the academic circle and the industry focus on the research goal of how to achieve higher light-emitting efficiency with lower energy source consumption. Theoretically, light emitted by the recombination of electrons and electric holes can radiate outside with 100% light-emitting efficiency. In reality, the internal structure and composition material of a light-emitting diode device will cause various types of light transmission losses, thus reduce the light-emitting efficiency.

To increase the light-emitting efficiency of light-emitting diodes, pattern technology has already been applied to sapphire substrate. For example, the light-emitting diode substrate 100 shown in FIG. 1 is a sapphire substrate 110, and a surface 130 of the sapphire substrate 110 is allocated with a plurality of triangular pyramid structures 120 with triangle bottoms 150 to scatter the light generated within the internal of the light-emitting diode, to avoid total reflection, and to increase the probability of the light penetrating the surface of the light-emitting diode. To increase the light-emitting efficiency, the pyramid structures 120 are arranged in a densest formation. Other types of pattern or pyramid designs are also gradually proposed.

Due to the material characteristics of a single-layer photoresist, however, it is difficult to accurately control the height and diameter of each cone on the sapphire substrate during the etching process. Consequently, it is unable to achieve better light-emitting efficiency for a light-emitting device due to the poor uniformities of the cone heights and diameters of cones on the sapphire substrate.

### SUMMARY OF THE INVENTION

Based on the problems of the prior arts, one of the purposes of the present invention is to provide a sapphire substrate structure for pattern etching and method of forming a pattern sapphire substrate to solve the problem of the poor uniformities of heights and diameters of the cones on the sapphire substrate.

Therefore, a sapphire substrate structure for pattern etching and method of forming a pattern sapphire substrate is proposed in the present invention. The sapphire substrate structure proposed in the present invention comprises a sapphire substrate, an underlayer covering the sapphire substrate, and a photoresist covering the underlayer. The photoresist layer is used to perform an etching process over the underlayer and the sapphire substrate after an exposure/development process.

Furthermore, the radius of the sapphire substrate structure of the present invention is preferred to be 2 inches, 4 inches, 6 inches, 8 inches, or 12 inches.

Furthermore, for the sapphire substrate structure of the present invention the underlayer is a homogeneous layer and comprises a flat surface.

Moreover, for the sapphire substrate structure of the present invention the material of the underlayer is an organic or an inorganic compound.

Furthermore, for the sapphire substrate structure of the present invention the photoresist is a homogeneous layer and comprises a flat surface.

Moreover, for the sapphire substrate structure of the present invention the material of the photoresist is G-line photoresist, I-line photoresist, 248 nm DUV photoresist, or 193 nm Arf photoresist.

Based on another purpose of the present invention, a method of forming a pattern sapphire substrate is proposed, and the method of forming a pattern sapphire substrate is for forming the substrate of a light-emitting device. The method of forming a pattern sapphire substrate comprises the following steps: applying a crystal growth process to form a sapphire substrate; applying a coating process to form an underlayer to cover the sapphire substrate; applying a coating process to form a photoresist layer to cover the underlayer.

Moreover, the method of forming a pattern sapphire substrate further comprises: applying an exposure/development process to form a photoresist pattern on the photoresist layer.

Moreover, the method of forming a pattern sapphire substrate further: applying the photoresist pattern and an etching process to form an underlayer pattern on the underlayer and a primary pattern sapphire substrate out of the sapphire substrate.

Moreover, the method of forming a pattern sapphire substrate further comprises the following step: performing a cleaning process to remove the photoresist pattern and the underlayer pattern, and trim the primary pattern sapphire substrate to form a pattern sapphire substrate.

As mentioned above, the sapphire substrate structure for pattern etching and method of forming a pattern sapphire substrate of the present invention may have one or more characteristics and advantages as described below:

(1). The underlayer of the pattern sapphire substrate structure comprises the characteristics of flatness and higher etching resistance.

(2). The pattern sapphire substrate structure is able to obtain better cone uniformity as the semiconductor processing technology is applied to form a plurality of cones.

In order to provide further understanding of the technical characteristics and the efficiency of the present invention, the same components in the following embodiments are labeled as the same numeral.

### BRIEF DESCRIPTION OF THE DRAWINGS

FIG. 1 is a three dimensional diagram showing a substrate of a light-emitting device according to a prior art.

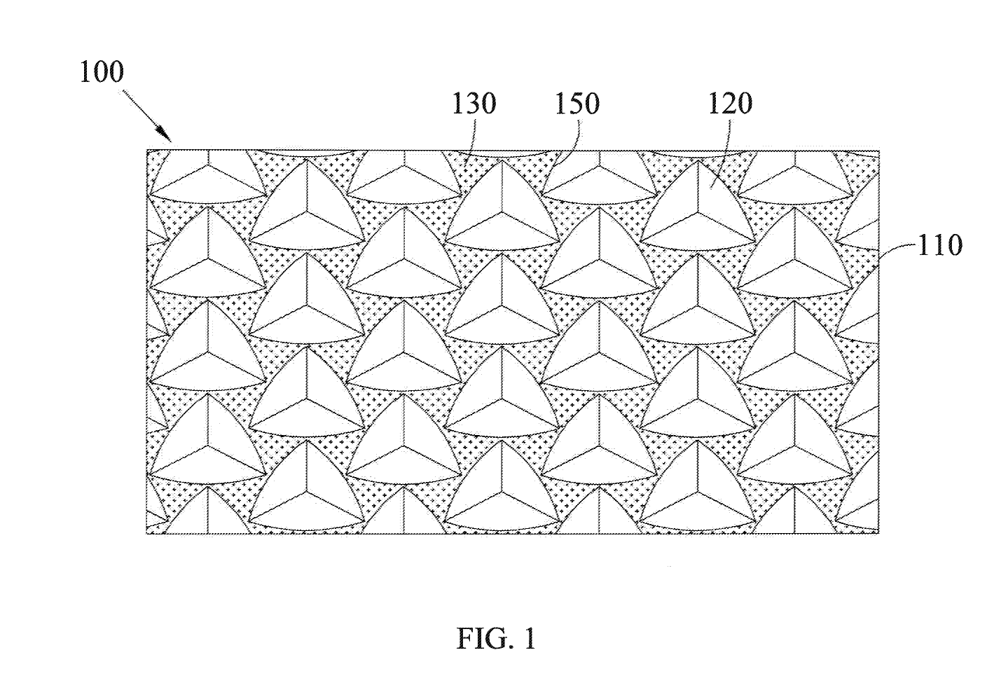

FIG. 2 is a side view diagram showing a sapphire substrate structure according to a preferred embodiment of the present invention.

FIG. 3 is a flow diagram showing a manufacturing method of the sapphire substrate structure according to the preferred embodiment of the present invention.

FIG. 4 is a side views diagram of an exposure/development procedure of the manufacturing method of the sapphire substrate structure according to the preferred embodiment of the present invention.

FIG. 5 is a side views diagram of an etching procedure of the manufacturing method of the sapphire substrate structure according to the preferred embodiment of the present invention.

FIG. 6 is a side views diagram of a cleaning procedure of the manufacturing method of the sapphire substrate structure according to the preferred embodiment of the present invention.

### DETAILED DESCRIPTION OF THE PREFERRED EMBODIMENTS

With reference to the drawings, thereafter, the preferred embodiment of a sapphire substrate structure for pattern etching and method of forming a pattern sapphire substrate in accordance with the present invention is illustrated. In order to be understood easily, the same components in the preferred embodiment are labeled as the same numeral.

The present invention discloses a sapphire substrate structure for pattern etching and method of forming a pattern sapphire substrate to solve the problem of the ill height and diameter uniformities of the cones on the sapphire substrate. The sapphire substrate structure proposed in the present invention comprises a sapphire substrate, an underlayer covering the sapphire substrate, and a photoresist covering the underlayer. After the sapphire substrate structure is formed, the sapphire substrate structure is step-by-step transformed into a pattern sapphire substrate with a plurality of cones through an exposure/development procedure, an etching procedure, and a cleaning procedure in sequence. The design of the cones is able to assist the light generated within the internal of a light-emitting device to penetrate outside and adequately increases the area of the surface of the light-emitting device to reduce the difficulty of the subsequent epitaxy. Besides, the apphire substrate structure of the present invention comprises an underlayer covering the sapphire substrate to improve the uniformities of the cone heights and diameters so as to improve the light-emitting efficiency. The sapphire substrate structure for pattern etching and method of forming a pattern sapphire substrate can be applied to various kind of light-emitting devices, for example a light-emitting diode.

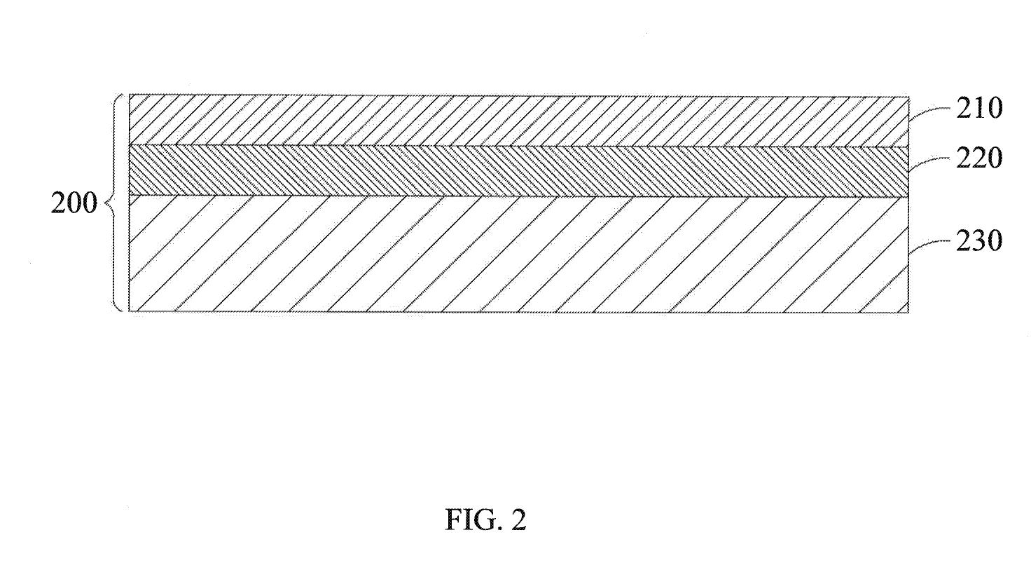

Referring to FIG. 2, FIG. 2 is a side view diagram showing a sapphire substrate structure according to a preferred embodiment of the present invention. In FIG. 2 the sapphire substrate structure 200 comprises a sapphire substrate 230, an underlayer 220 covering the sapphire substrate 230, and a photoresist 210 covering the underlayer 220. The photoresist layer 210 is used to perform an etching process over the underlayer 220 and the sapphire substrate 230 after an exposure/development process. The radius of the sapphire substrate structure of the present invention is preferred to be 2 inches, 4 inches, 6 inches, 8 inches, or 12 inches.

Furthermore, for the sapphire substrate structure 200 of the present invention the underlayer 220 is a homogeneous layer and comprises a flat surface.

Moreover, for the sapphire substrate structure 200 of the present invention the material of the underlayer 220 is an organic compound or an inorganic compound.

Furthermore, for the sapphire substrate structure 200 of the present invention the photolayer 210 is a homogeneous layer and comprises a flat surface.

Moreover, for the sapphire substrate structure 200 of the present invention the material of the photoresist 210 is G-line photoresist, I-line photoresist; 248 nm DUV photoresist, or 193 nm Arf photoresist.

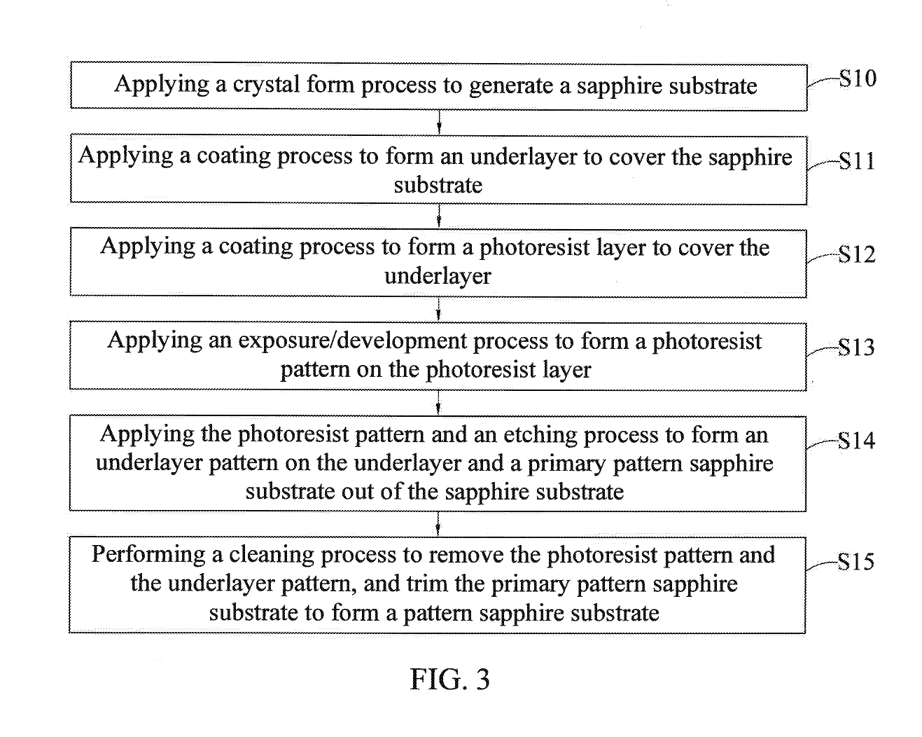

Referring to FIG. 3, FIG. 3 is a flow diagram showing a manufacturing method of the sapphire substrate structure according to the preferred embodiment of the present invention. In FIG. 3 the step flow is as follows: S10: applying a crystal growth process to form a sapphire substrate; S11: applying a coating process to form an underlayer to cover the sapphire substrate; S12: applying a coating process to form a photoresist layer to cover the underlayer; S13: applying an exposure/development process to form a photoresist pattern on the photoresist layer; S14: applying the photoresist pattern and an etching process to firm an underlayer pattern on the underlayer and a primary pattern sapphire substrate out of the sapphire substrate; S15: performing a cleaning process to remove the photoresist pattern and the underlayer pattern, and trim the primary pattern sapphire substrate to form a pattern sapphire substrate.

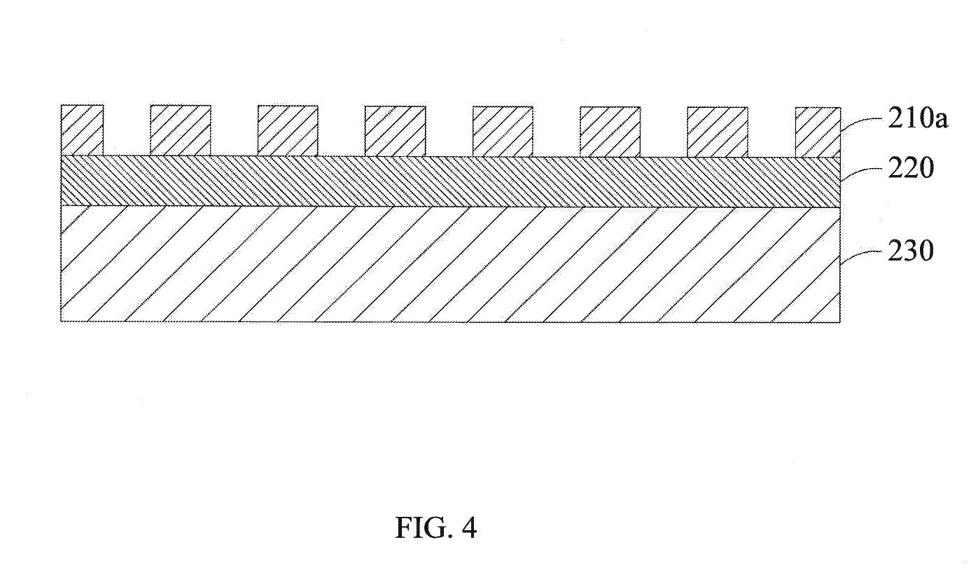

Referring to FIG. 4, FIG. 4 is a side views diagram of an exposure/development procedure of the manufacturing method of the sapphire substrate structure according to the preferred embodiment of the present invention. In FIG. 4 the pattern area of the photoresist 210 is exposed and developed to form a photoresist pattern 210a on the photoresist 210.

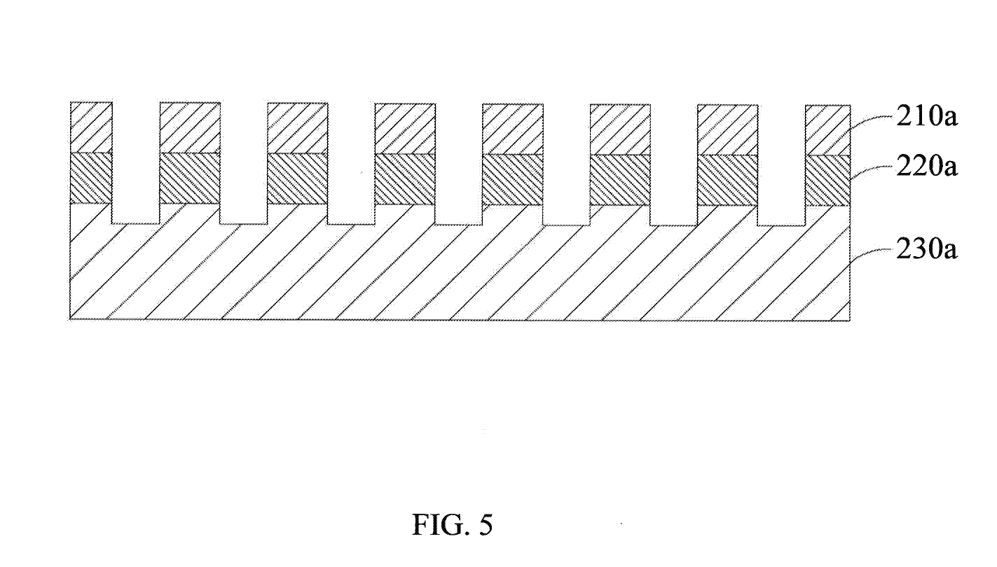

Referring to FIG. 5, FIG. 5 is a side views diagram of an etching procedure of the manufacturing method of the sapphire substrate structure according to the preferred embodiment of the present invention. In FIG. 5 the photoresist pattern 210a is utilized as a etching mask to etch the underlayer 220 to obtain a underlayer pattern 220a, then the underlayer pattern 220a is utilized as a etching mask to etch the sapphire substrate 230 to form the primary pattern sapphire substrate 230.

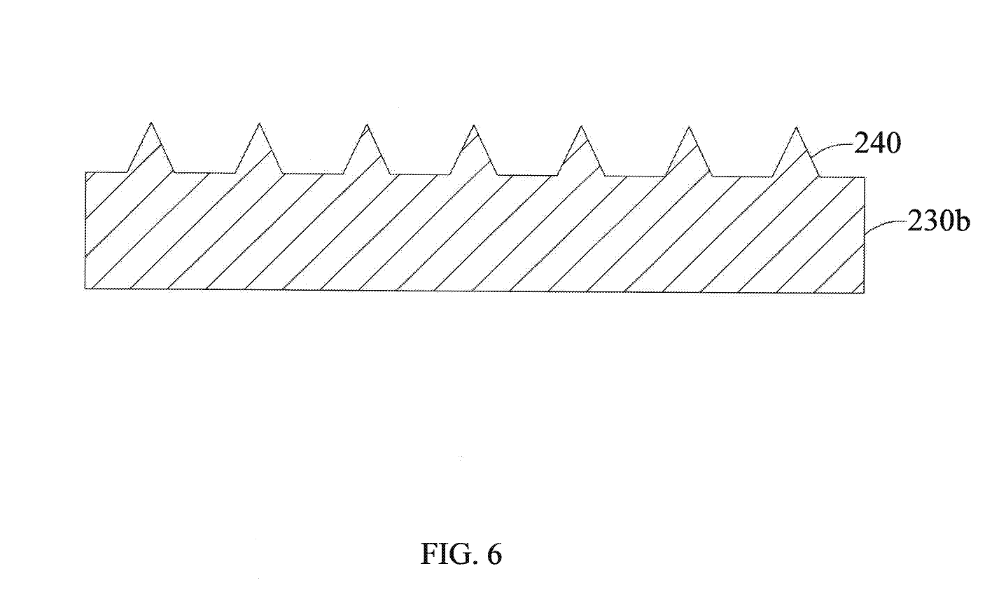

Referring to FIG. 6, FIG. 6 is a side views diagram of a cleaning procedure of the manufacturing method of the sapphire substrate structure according to the preferred embodiment of the present invention. In FIG. 6 it shows that the photoresist pattern 210a and the underlayer pattern 220a are removed after the cleaning procedure, and the primary pattern sapphire substrate 230a is trimmed to form a plurality of cones 240 so as to finally form the pattern sapphire substrate 230b.

The present invention has been described with reference to the foregoing preferred embodiments, it will be understood that the invention is not limited to the details thereof. Various equivalent variations and modifications may still occur to those skilled in this art in view of the teachings of the present invention. Thus, all such variations and equivalent modifications are also embraced within the scope of the invention as defined in the appended claims.

What is claimed is:

1. A sapphire substrate structure for pattern etching, comprising:
a sapphire substrate;
an underlayer covering the sapphire substrate; and
a photoresist covering the underlayer, wherein the photoresist layer is used to perform an etching process on the underlayer and the sapphire substrate after an exposure process and a development process.

2. The sapphire substrate structure of claim 1, wherein a radius of sapphire substrate structure is 2 inches, 4 inches, 6 inches, 8 inches, or 12 inches.

3. The sapphire substrate structure of claim 1, wherein the underlayer is a homogeneous layer and has a flat surface.

4. The sapphire substrate structure of claim 3, wherein the material of the underlayer is an organic compound or an inorganic compound.

5. The sapphire substrate structure of claim 1, wherein the photoresist is a homogeneous layer and has a flat surface.

6. The sapphire substrate structure of claim 5, wherein the material of the photoresist is G-line photoresist, I-line photoresist, 248 nm DUV photoresist, or 193 nm Arf photoresist.

7. A method of forming a pattern sapphire substrate, comprising:
applying a crystal growth process to form a sapphire substrate;
applying a coating process to form an underlayer to cover the sapphire substrate; and
applying a coating process to form a photoresist layer to cover the underlayer.

8. The method of claim 7, further comprising:
applying an exposure/development process to form a photoresist pattern on the photoresist layer.

9. The method of claim 8, further comprising:
forming an underlayer pattern on the underlayer and a primary pattern sapphire substrate by applying the photoresist pattern and an etching process on the sapphire substrate.

10. The method of claim 8, further comprising the following step:
performing a cleaning process to remove the photoresist pattern and the underlayer pattern, and trim the primary pattern sapphire substrate to form the pattern sapphire substrate.
